(19) United States
(12) Patent Application Publication
(10) Pub. No.: US 2009/0114146 A1
(43) Pub. Date: May 7, 2009

(54) Method for Manufacturing Semiconductor Device and Substrate Processing Apparatus

(75) Inventors: Yushin Takasawa, Toyama-shi (JP); Naonori Akae, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 11/992,401

(22) PCT Filed: Dec. 28, 2006
(86) PCT No.: PCT/JP2006/326204

§ 371 Date: Jun. 9, 2008

(30) Foreign Application Priority Data
Dec. 28, 2005 (JP) 2005-378735

(51) Int. Cl. C30B 33/06; C30B 23/00; C30B 35/00

(52) U.S. Cl. 117/1; 117/84; 117/106; 118/725

(57) ABSTRACT

To provide a method for manufacturing a semiconductor device and a substrate processing apparatus which contribute to forming high-density nuclei. The method for manufacturing a semiconductor device according to the invention includes the steps of: carrying a wafer 200 having an insulator film on the surface into a reaction tube 203; introducing silicon-based gas into the reaction tube 203 to form silicon grains on the insulator film formed on the surface of the wafer 200; and carrying the processed wafer 200 out from the reaction tube 203. Before the introduction of the silicon-based gas, dopant gas is introduced into the reaction tube 203.

### TECHNICAL FIELD

The present invention relates to a method for manufacturing a semiconductor device including the process of forming island-pattern fine silicon nanograins and the process of forming fine polysilicon grains and to a substrate processing apparatus.

### BACKGROUND ART

The thickness of tunnel oxide film is tending to decrease as flash memories decrease in size and operating power is decreased with low power consumption. However, with the decrease in thickness, device reliability can be decreased because of dielectric breakdown and stress-inductive leak current. Therefore, unlike a floating gate type and an insulation trap type, a silicon nanocrystal memory with an intermediate memory structure has come to attract attention.

Another concern is that process variations in polysilicon crystal grains of gate electrodes may cause variations in electric characteristic in a tendency to decrease in the area of the gate electrodes as the packaging density of DRAMs increases. Therefore, it is under consideration to decrease the variations in gate electrodes by decreasing the grain size of polysilicon.

It is therefore desired to develop a silicon nanocrystal memory technique and a fine polysilicon forming technique by controlling the initial stage of growing a silicon film on an insulator film. However, it was difficult to form fine grains because the influence of the surface of the insulator film which is important in the initial stage of silicon film deposition could not be grasped.

While conditions for forming silicon nanocrystal must be optimized to form fine grains, control of the state of the insulator film is important to form fine grains with high reproducibility because the density of silicon grains is significantly influenced by the surface state.

### DISCLOSURE OF THE INVENTION

### Problems to be Solved by the Invention

In the silicon nanocrystal memory technique and the fine polysilicon forming technique, nuclear density must be increased in the process of forming grains on the wafer surface. However, in conventional nucleation, nuclear density is generally controlled only by controlling process conditions. This method produces the problem of difficulty in achieving a nuclear density appropriate to nanoscale order, requiring to find the cause and take measures.

Accordingly, the objective of the invention is to solve the problems of the relate art to provide a method for manufacturing a semiconductor device and a substrate processing unit which contribute to forming high-density nuclei.

### Means for Solving the Problems

A first characteristic of the invention is a method for manufacturing a semiconductor device, including the steps of: carrying a substrate having an insulator film on the surface into a processing chamber; introducing silicon-based gas into the processing chamber to form silicon grains on the insulator film formed on the surface of the substrate; and carrying the processed substrate out from the processing chamber; wherein before the introduction of the silicon-based gas, dopant gas is introduced into the processing chamber.

Preferably, the dopant gas is introduced into the processing chamber also during the introduction of the silicon-based gas.

Preferably, the method further includes the step of cleaning the surface of the insulator film formed on the surface of the substrate before the step of carrying the substrate into the processing chamber.

Preferably, the method further includes the step of cleaning the surface of the insulator film formed on the surface of the substrate with a dilute hydrofluoric solution before the step of carrying the substrate into the processing chamber.

Preferably, in the process of forming silicon grains, island-pattern silicon grains are formed by stopping the growth of silicon grains before the silicon grains come into contact with one another.

Preferably, in the process of forming silicon grains, continuous silicon grains are formed by continuing the growth of silicon grains until the silicon grains come into contact with one another.

Preferably, the silicon-based gas is SiH₄ or Si₂H₆ and the dopant gas is PH₃, B₂H₆, BCl₃, or AsH₃.

A second characteristic of the invention is a method for manufacturing a semiconductor device, including the steps of: carrying a substrate having an insulator film on the surface into a processing chamber; introducing silicon-based gas into the processing chamber to form island-pattern silicon grains on the insulator film formed on the surface of the substrate; and carrying the processed substrate out from the processing chamber; wherein before and/or during the introduction of the silicon-based gas, dopant gas is introduced into the processing chamber.

Preferably, the method further includes the step of cleaning the surface of the insulator film formed on the surface of the substrate before the step of carrying the substrate into the processing chamber.

A third characteristic of the invention is a substrate processing unit including: a processing chamber for processing a substrate having an insulator film on the surface; a silicon gas feed system for feeding silicon-based gas into the processing chamber; a dopant gas feed system for feeding dopant gas into the processing chamber; an exhaust system for exhausting the processing chamber; a heater for heating the substrate in the processing chamber; and a controller that controls the substrate processing unit so as to feed silicon-based gas into the processing chamber to form silicon grains on the insulator film formed on the surface of the substrate, and to feed dopant gas into the processing chamber before the introduction of the silicon-based gas.

Preferably, the controller controls the substrate processing unit so as to feed dopant gas into the processing chamber also during the introduction of the silicon-based gas.

A fourth characteristic of the invention is a substrate processing unit including: a processing chamber for processing a substrate having an insulator film on the surface; a silicon gas feed system for feeding silicon-based gas into the processing chamber; a dopant gas feed system for feeding dopant gas into the processing chamber; an exhaust system for exhausting the processing chamber; a heater for heating the substrate in the processing chamber; and a controller that controls the substrate processing unit so as to feed silicon-based gas into the processing chamber to form island-pattern silicon grains on the insulator film formed on the surface of the substrate, and to feed dopant gas into the processing chamber before and/or during the introduction of the silicon-based gas.

### Advantages of the Invention

The invention provides a method for manufacturing a semiconductor device and a substrate processing unit capable of controlling formation of the nuclei of high-density silicon grains with stable performance.

### BRIEF DESCRIPTION OF THE DRAWINGS

FIG. 1 is a plan view of a substrate processing unit according to an embodiment of the invention.

FIG. 2 is a sectional view of the substrate processing unit shown in FIG. 1.

FIG. 3 is a schematic sectional view of a furnace of the substrate processing unit according to the embodiment of the invention.

FIG. 4 is a schematic diagram illustrating the process of forming silicon quantum dots and polysilicon.

FIG. 5 is a graph showing the relationship between the deposition time and an increase in film thickness of Example 1 of the invention.

FIG. 6 shows images of reactions in Example 1 of the invention, wherein (a) shows a case without pre-cleaning and (b) shows a case with pre-cleaning.

FIG. 7 shows electron micrographs in Example 2 of the invention, showing the effects of silicon grain density control depending on whether dopant gas is introduced or not and difference in the timing of the introduction.

FIG. 8 is a diagram showing the timing of introduction of silicon-based gas and dopant gas in Example 2 of the invention.

FIG. 9 is a sectional view showing part of a flash memory including a floating gate constructed of silicon quantum dots.

FIG. 10 is a sectional view showing part of a DRAM including a gate electrode constructed of a fine-grain polysilicon film and a metal film.

FIG. 11 shows images of reactions in the case where dopant gas is introduced before and/or during the process of forming silicon grains (FIG. 11(b)) and in the case where no dopant gas is introduced (FIG. 11(a)).

### DESCRIPTION OF REFERENCE NUMERALS AND SIGNS

10 substrate processing unit

100 pod

100a cap

101 casing

103 first transfer chamber

105 IO stage

108 pod opener

112 first wafer conveying unit

115 elevator

121 second transfer chamber

122 spare room for carrying-in

123 spare room for carrying-out

124 second wafer conveying unit

125 casing

126 elevator

127 gate valve

132 linear actuator

134 wafer carrying-in/out port

136 driving mechanism

137 second furnace

138 first cooling unit

139 second cooling unit

140 substrate table for carrying-in room

141 substrate table for carrying-out

142 closer

200 wafer

202 first furnace

203 reaction pipe

217 wafer support table

207a upper heater

207b lower heater

209a gas intake flange

209b gas exhaust flange

231 exhaust line

232a first gas intake line

232b second gas intake line

240a first valve

240b second valve

240c fourth valve

240d fifth valve

241a first massflow controller

241b second massflow controller

241c third massflow controller

242a first valve

242b second valve

242c third valve

243a first gas source

243b second gas source

243c third gas source

244 gate valve

247a temperature controller

247b temperature controller

248 pressure controller

249 main controller

250 vacuum pump

301 source

302 drain

303 channel region

304 tunnel oxide film

305 floating gate electrode

305a silicon quantum dot

306 insulating layer

307 control gate electrode

### BEST MODE FOR CARRYING-OUT THE INVENTION

In a conventional method for forming silicon nanocrystal memory using silicon quantum dots, first, silicon-based gas is introduced into a processing chamber having a substrate therein to form island-pattern silicon grains, that is, silicon quantum dots on the substrate not by doping, the substrate is then taken out from the processing chamber, and the silicon quantum dots formed by ion plantation or the like are subjected to doping. The inventor has found that silicon quantum dots can be formed while doping impurities by adding dopant gas during the formation of silicon quantum dots. Furthermore, the inventor has found an expected unknown effect that the nuclear density of silicon grains can be increased by applying dopant gas before and/or the process of forming silicon quantum dots, that is, before and/or during introduction of silicon-based gas. The present invention is based on the findings of the inventor.

The invention relates to a method including the process step of forming fine silicon grains for forming a silicon nanocrystal memory or gate electrodes using silicon quantum dots, for example, on the surface of an insulator film of a semiconductor chip, wherein the nuclear density of the silicon grains is increased by applying dopant gas before and/or during the process step of forming the fine silicon grains.

An embodiment of the invention will be described with reference to the drawings.

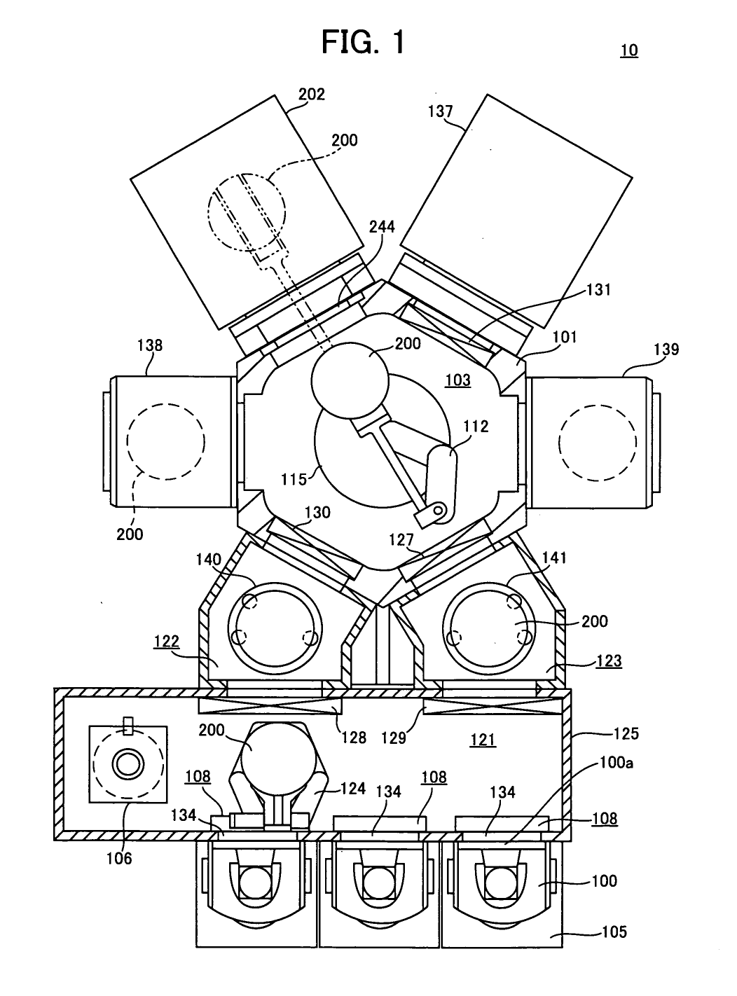

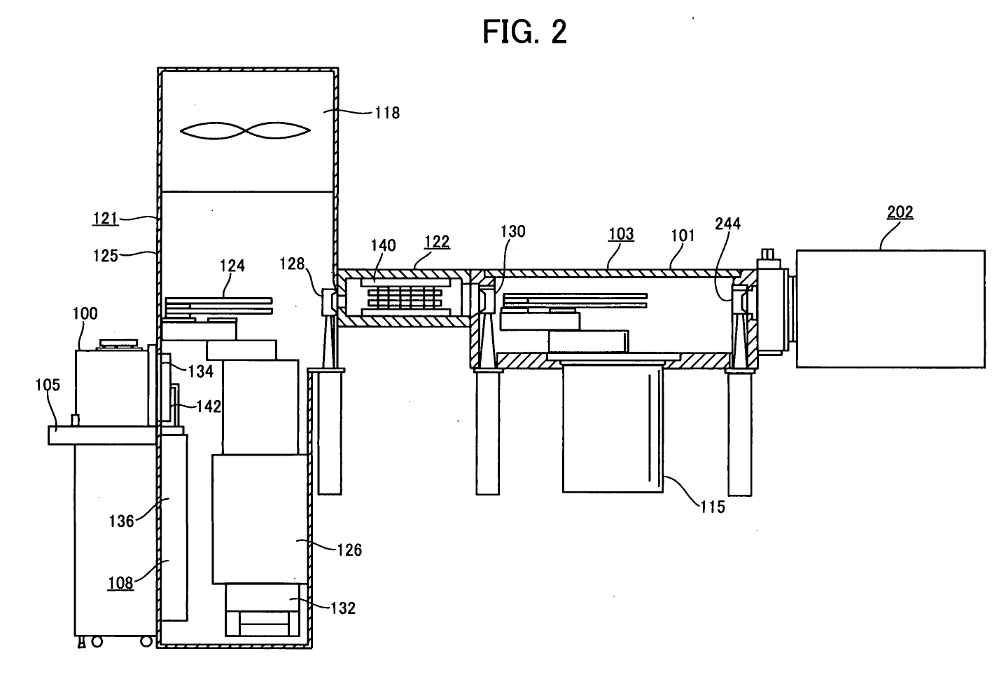

Referring first to FIGS. 1 and 2, the outline of a substrate processing unit 10 incorporating the invention will be described.

The substrate processing unit 10 of the invention uses a front opening unified pod (FOUP, hereinafter, referred to as a pod) as a carrier for transporting a substrate such as a wafer. In the following description, the front, rear, right, and left are based on FIG. 1. That is, the front is the lower part pf FIG. 1, the rear is the upper part, and the right and left are the right and left of FIG. 1.

As shown in FIGS. 1 and 2, the substrate processing unit 10 has a first transfer chamber 103 with a load lock chamber structure to withstand a pressure (negative pressure), such as vacuum, below atmospheric pressure. The casing 101 of the first transfer chamber 103 is shaped like a hexagonal box in plan view whose upper and lower ends are closed. The first transfer chamber 103 has a first wafer conveying unit 112 which conveys two wafers 200 at the same time under negative pressure. The first wafer conveying unit 112 can be moved up and down by an elevator 115 while maintaining the airtightness of the first transfer chamber 103.

A carrying-in spare room 122 and a carrying-out spare room 123 are connected to two front side walls of the six side walls of the casing 101 through gate valves 244 and 127, respectively. The spare room 122 and the spare room 123 each have a load lock chamber structure that withstands negative pressure. The spare room 122 has a substrate carrying-in table 140 and the spare room 123 has a substrate carrying-out table 141.

A second transfer chamber 121 used under substantially atmospheric pressure is connected to the front of the spare room 122 and the spare room 123 through gate valves 128 and 129, respectively. The second transfer chamber 121 has a second wafer conveying unit 124 for conveying the wafers 200. The second wafer conveying unit 124 is moved up and down by an elevator 126 disposed in the second transfer chamber 121 and is moved to the right and left by a linear actuator 132.

As shown in FIG. 1, a notch or flat aligner 106 is disposed on the left of the second transfer chamber 121. As shown in FIG. 2, a clean unit 118 for feeding clean air is disposed at the upper part of the second transfer chamber 121.

As shown in FIGS. 1 and 2, wafer carrying-in/out ports 134 for carrying in and out the wafers 200 to/from the second transfer chamber 121 and pod openers 108 are disposed at the front of the casing 125 of the second transfer chamber 121. An IO stage 105 is disposed opposite to each pod opener 108 with the wafer carrying-in/out port 134 therebetween, that is, outside the casing 125. The pod opener 108 has a closer 142 which can open and close the cap 100a of the pod 100 and can close the wafer carrying-in/out port 134 and a driving mechanism 136 for driving the closer 142. The pod opener 108 allows the wafers 200 to be taken in and out from the pod 100 by opening and closing the cap 100a of the pod 100 placed on the IO stage 105. The pod 100 is moved onto and from the IO stage 105 by a rail guided vehicle (RGV, not shown).

As shown in FIG. 1, of the six side walls of the casing 101, the two adjacent rear (back) side walls connect to a first furnace 202 and a second furnace 137 through gate valves 130 and 131, respectively. The first furnace 202 and the second furnace 137 are of a hot wall type. Of the six side walls of the casing 101, the remaining two opposing side walls connect to a first cooling unit 138 and a second cooling unit 139, respectively. The first cooling unit 138 and the second cooling unit 139 cool the processed wafer 200.

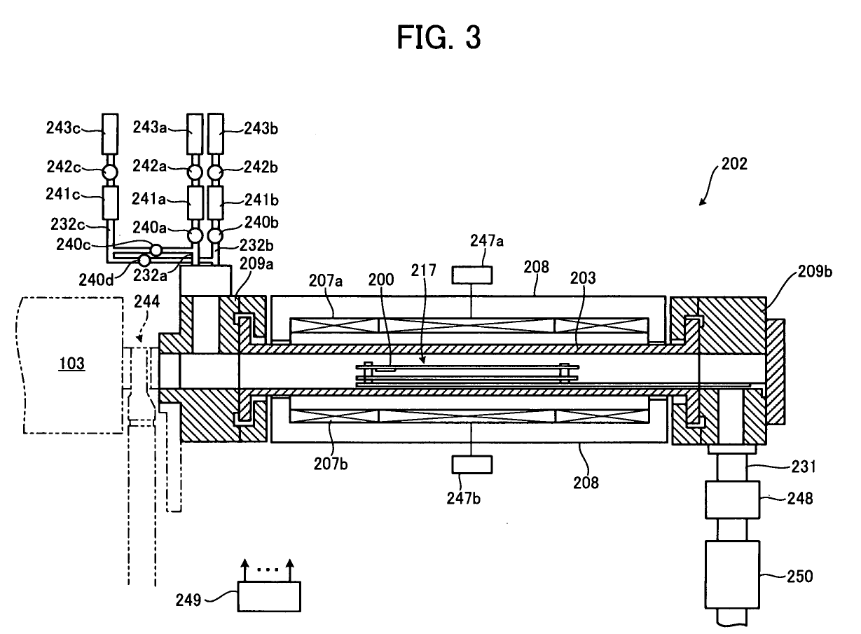

Referring to FIG. 3, the outline of the first furnace 202 of the substrate processing unit 10 according to the embodiment of the invention will be described. FIG. 3 is a schematic longitudinal section of the first furnace 202 of the substrate processing unit 10 according to the embodiment of the invention.

A reaction pipe 203 or a reaction vessel made of quartz, silicon carbide, or alumina has a horizontal flat space serving as a processing chamber, in which a wafer 200 or a substrate is carried. The reaction pipe 203 has therein a wafer support table 217 for supporting the wafer 200, and has, at both ends, a gas intake flange 209a and a gas exhaust flange 209b serving as airtight manifolds. The gas intake flange 209a connects to the first transfer chamber 103 through the gate valve 244 serving as a sluice valve.

The gas intake flange 209a connects to a first gas intake line 232a and a second gas intake line 232b serving as feed tubes. The first gas intake line 232a and the second gas intake line 232b connect to a first gas source 243a and a second gas source 243b, respectively. The first gas intake line 232a has, at a midpoint, a first massflow controller 241a, serving as a flow rate controller (flow rate control means) for controlling the flow rate of first gas to be introduced to the reaction pipe 203 from the first gas source 243a, and first valves 242a and 240a upstream and downstream of the first massflow controller 241a. The second gas intake line 232b has, at a midpoint, a second massflow controller 241b, serving as a flow rate controller (flow rate control means) for controlling the flow rate of second gas to be introduced to the reaction pipe 203 from the second gas source 243b, and second valves 242b and 240b upstream and downstream of the second massflow controller 241b.

The first gas intake line 232a and the second gas intake line 232b connect to a third gas intake line 232c. The third gas intake line 232c connects to a third gas source 243c, and at a midpoint, a third massflow controller 241c for controlling the flow rate of a third gas to be introduced to the reaction pipe 203 from the third gas source and a third valve 242c upstream thereof. The third gas intake line 232c branches to two lines downstream of the third massflow controller 241c, which are connected to the portion of the first gas intake line 232a downstream of the first valve 240a of the first gas intake line 232a and to the portion of the second gas intake line 232b downstream of the second valve 240b of the second gas intake line 232b to allow the third gas to be supplied to each line. The branch lines of the third gas intake line 232c have a fourth valve 240c and a fifth valve 240d, respectively. In this embodiment, the third gas source 243 contains, as the third gas, inert gas, such as N₂, Ar, or He.

The gas exhaust flange 209b connects to an exhaust line 231 serving as an exhaust pipe. The exhaust line 231 connects to a vacuum pump 250 serving as an evacuation unit (exhaust means) for evacuating the reaction pipe 203, at a midpoint of which a pressure controller 248 serving as a pressure control section (pressure control means) for controlling the pressure in the reaction pipe 203 is provided.

An upper heater 207a and a lower heater 207b serving as heating mechanisms (heating means) are provided on and under the reaction pipe 203, to heat the interior of the reaction pipe 203 evenly or with a predetermined temperature gradient. The upper heater 207a and the lower heater 207b connect to temperature controllers 247a and 247b, respective, serving as temperature control sections (temperature control means) for controlling the temperatures of the heaters. A thermal insulator 208 or a thermal insulation member is disposed to cover the upper heater 207a, the lower heater 207b, and the reaction pipe 203.

The temperature and pressure in the reaction pipe 203 and the flow rate of the gas to be introduced to the reaction pipe 203 are controlled to a predetermined temperature, pressure, and flow rate by the temperature controllers 247a and 247b, the pressure controller 248, and the massflow controllers 241a, 241b, and 241c, respectively. The temperature controllers 247a and 247b, the pressure controller 248, and the massflow controllers 241a, 241b, and 241c are controlled by a main controller 249 serving as a main control section (main control means). The main controller 249 also controls the closing and opening of the valves 242a, 240a, 242b, 240b, 242c, 240c, and 240d to control the gas feed timing. The main controller 249 also controls the operations of the components of the substrate processing unit 10.

A method for processing a wafer or a substrate using the first furnace 202 of the substrate processing unit 10, as one of the process steps of manufacturing a semiconductor device, will be described. In the following description, the operations of the components of the substrate processing unit are controlled by the main controller 249.

In the process step before this process, the wafer 200 serving as a substrate having semiconductor chips is coated with a thin insulator film made of silicon oxide or the like. The control of the thickness of the insulator film is very important because it influences the electrical performance. Therefore, the wafer 200 has not been cleaned after a thin insulator film is formed and before the process of forming silicon grains.

In contrast, in this embodiment, a wafer having semiconductor chips is cleaned using, for example, a dilute hydrofluoric (DHF) solution to remove the contaminants on the surface, such as a spontaneous oxide film or organic contaminants before carrying the wafer into the substrate processing unit. The wafer is then dried by a spin dryer or the like and is transported quickly in the cleaned state to a spare room in the substrate processing unit. The reason why the wafer is processed quickly in the cleaned state is to prevent a bad influence due to the contamination of the atmosphere in the clean room. The contamination during transportation of the substrate to the substrate processing unit must be controlled. If a lot of contaminants are adhered to the wafer surface at that time, silicon grains of a desired size and density cannot be formed because the density of the bonds of silicon is different between the surface of the insulator film and the surface with organic contaminants, causing a decrease in the yield of semiconductor devices.

In this embodiment, after the surface of the insulator film formed on the substrate is cleaned, the substrate is quickly put into the substrate processing unit, where it is processed in the cleaned state. This allows silicon grains to be formed irrespective of the state of preservation of the substrate surface, allowing the silicon grains to be formed with stability.

The unprocessed wafers 200 whose surfaces have cleaned are conveyed to the substrate processing unit for executing the process by the rail guided vehicle, with 25 wafers accommodated in each pod 100. As shown in FIGS. 1 and 2, the pod 100 conveyed is transferred from the rail guided vehicle onto the IO stage 105. The cap 100a of the pod 100 is removed by the pod opener 108 to open the wafer inlet-outlet opening of the pod 100.

When the pod 100 is opened by the pod opener 108, the second wafer conveying unit 124 in the second transfer chamber 121 picks up the wafer 200 from the pod 100 into the spare room 122, and places the wafer 200 on the substrate table 140. During the transfer operation, the gate valve 130 of the spare room 122 adjacent to the first transfer chamber 103 is closed so that the negative pressure in the first transfer chamber 103 is maintained. The transfer of a predetermined number of, for example, 25 wafers 200 accommodated in the pod 100 has been completed to the substrate table 140, the gate valve 128 is closed, and the spare room 122 is evacuated to a negative pressure by an exhaust unit (not shown).

When the spare room 122 reaches a preset pressure, the gate valve 130 is opened to communicate the spare room 122 with the first transfer chamber 103. Subsequently, the first wafer conveying unit 112 of the first transfer chamber 103 picks up two wafers 200 at a time from the substrate table 140 and carries them into the first transfer chamber 103. After the gate valve 130 is closed, the first transfer chamber 103 and the first furnace 202 are communicated. That is, with the temperature in the reaction pipe 203 maintained at a process temperature by the heaters 207a and 207b, the gate valve 244 is opened, and the wafers 200 are carried into the reaction pipe 203 by the first wafer conveying unit 112 and placed on the wafer support table 217. In this embodiment, two wafers 200 are placed on the wafer support table 217 and processed at the same time. The two wafers 200 are transferred to the reaction pipe 203 at the same time so that their heat histories are equal. At the same time the wafers 200 are carried into the reaction pipe 203, preheating is started until the reaction pipe 203 reaches a wafer 200 processing temperature. One wafer 200 may be placed on the wafer support table 217 so that one wafer 200 is processed at a time. In that case, a dummy wafer may be placed on the part of the wafer support table 217 which supports no wafer 200.

After the first wafer conveying unit 112 is retracted and the gate valve 244 is closed, the pressure in the reaction pipe 203 is controlled (stabilized) to the processing pressure by the pressure controller 248, and the temperature in the reaction pipe 203 is controlled (stabilized) by the temperature controllers 247a and 247b so that the wafer temperature reaches the processing temperature. When the pressure in the reaction pipe 203 and the temperature of the wafers 200 are stabilized, inertia gas is introduced into the reaction pipe 203 by at least one of the first gas intake line 232a and the second gas intake line 232b from the third gas source 243c through the third gas intake line 232c so that the reaction pipe 203 is filled with the inertia gas.

After the pressure in the reaction pipe 203 is stabilized to the processing pressure and the temperature of the wafers 200 is stabilized to the processing temperature, processing gas is introduced into the reaction pipe 203, so that the wafers 200 are processed. That is, silicon grains are formed on the insulator film on the wafers 200.

The silicon grains are formed by introducing silicon-based gas such as SiH₄ or SiH₆ to the reaction pipe 203. In general, the density of the silicon grains is from 10¹⁰/cm² to 10¹¹/cm². As the gate electrodes decrease in length with higher degree of integration of a device, fine high-density silicon grains are required to reduce the variations. However, it was difficult for the conventional method to form silicon grains with a target level of 10¹²/cm².

Therefore, the process of the invention adopts a method for increasing the density of silicon grains using dopant gas such as PH₃, B₂H₆, BCl₃, or AsH₃.

That is, in the embodiment, the first gas source 243a contains silicon-based gas such as SiH₄ or Si₂H₆ as a first gas, and the second gas source 243b contains dopant gas such as PH₃, B₂H₆, BCl₃, or AsH₃ as a second gas. After the pressure in the reaction pipe 203 is stabilized to a processing pressure and the temperature of the wafer 200 is stabilized to a processing temperature, silicon-based gas serving as a first gas and dopant gas serving as a second gas are introduced into the reaction pipe 203 from the first gas source 243a and the second gas source 243b through the first gas intake line 232a and the second gas intake line 232b, respectively, at the timing, discussed below, so that silicon grains are formed on the insulator film formed on the wafer 200.

Specifically, (1) dopant gas is first introduced into the reaction pipe 203, and after the introduction of the dopant gas is stopped, silicon-based gas is introduced to form silicon grains; (2) dopant gas and silicon-based gas are introduced at the same time to form-silicon grains; or (3) dopant gas is first introduced, and silicon-based gas is introduced, with the dopant gas introduced, to form silicon grains.

In other words, (1) before the process of forming silicon grains, (2) during the process of forming silicon grains, or (3) before and during the process of forming silicon grains, dopant gas is introduced to the processing chamber. This allows silicon grains with 10¹²/cm² level to be formed, as discussed below.

The conditions for processing wafers in the furnace of the embodiment, that is, the conditions for forming silicon grains on the insulator film formed on the wafer surface are, for example, processing temperature: 200-800° C., processing pressure: 13-1,330 Pa, the flow rate of silicon-based gas (SiH₄): 10-2,000 sccm, and the flow rate of dopant gas (B₂H₆): 10-2,000 sccm. Maintaining the process conditions at predetermined values in the respective ranges allows silicon grains with many nucleation sites to be formed.

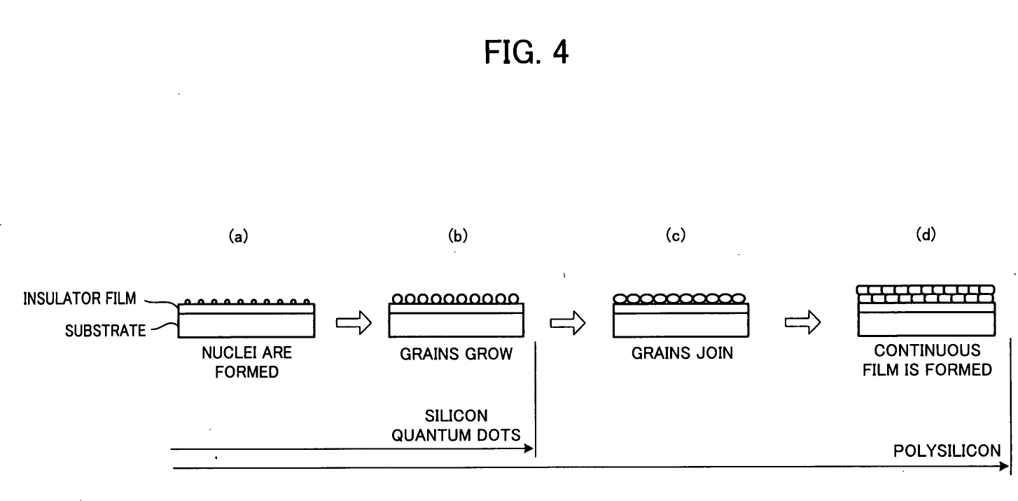

Referring to FIG. 4, the process from nucleation to continuous film deposition will be described. When silicon-based gas is supplied, nuclei are formed on the insulator film on the surface of the substrate, as shown in FIG. 4(a). Thereafter, crystals grow around the nuclei, as shown in FIG. 4(b). The grown crystals are called grains. When the grains grow further, they come into contact with each other, as shown in FIG. 4(c), into a continuous polysilicon film without clearance between the grains, as shown in FIG. 4(d). Stopping the growth in the state in which the grains are separate before the contact allows formation of island-pattern silicon grains, that is, silicon quantum dots.

In this embodiment, high nuclear density is achieved by introducing dopant gas before and/or during the process of forming grains, that is, before and/or during feeding of silicon-based gas. This can increase the density of silicon grains in forming silicon quantum dots, and decrease the grain size of polysilicon film in forming a polysilicon film.

Upon completion of the process of the wafers 200, inert gas or the third gas is introduced to the reaction pipe 203 from the third gas source 243c through the third gas intake line 232c and at least one of the gas intake lines 232a and 232b so that so that the residual gas is purged from the reaction pipe 203 through the exhaust line 231.

After the residual gas is purged, the pressure in the reaction pipe 203 is controlled to wafer conveying pressure by the pressure controller 248. After the pressure in the reaction pipe 203 reaches the conveying pressure, the processed wafers 200 are carried out from the reaction pipe 203 to the first transfer chamber 103 by the first wafer conveying unit 112. That is, after the process to the wafer 200 is completed in the first furnace 202 and the purge is finished, the gate valve 244 is opened, and the two processed wafers 200 are conveyed to the first transfer chamber 103 by the first wafer conveying unit 112. After the transfer, the gate valve 244 is closed.

The first wafer conveying unit 112 transfers the two wafers 200 carried out from the first furnace 202 to the first cleaning unit 138, where the two processed wafers 200 are cooled.

After conveying the processed wafers 200 to the first cooling unit 138, the first wafer conveying unit 112 picks up two wafers 200 prepared on the substrate table 140 in the spare room 122 at a time and conveys them to the first furnace 202, as in the above-described operation, and performs a desired process to the two wafers 200 in the first furnace 202.

After a preset cooling time has passed in the first cooling unit 138, the cooled two wafers 200 are conveyed from the first cooling unit 138 to the first transfer chamber 103 by the first wafer conveying unit 112.

After the two cooled wafers 200 are conveyed from the first cooling unit 138 to the first transfer chamber 103, the gate valve 127 is opened. The first wafer conveying unit 112 conveys the two wafers 200 conveyed from the first cooling unit 138 to the spare room 123, and places them on the substrate table 141, and thereafter, the spare room 123 is closed by the gate valve 127.

The above operation is repeated, so that a predetermined number of, for example, 25 wafers 200 conveyed to the spare room 122 are processed in sequence by two.

After all the wafers 200 carried in the spare chamber 122 are processed and housed in the spare chamber 123, and then the spare chamber 123 is closed by the gate valve 127, the spare chamber 123 is returned to substantially atmospheric pressure by inert gas. When the spare chamber 123 is returned to substantially atmospheric pressure, the gate valve 129 is opened and the cap 100a of an unoccupied pod 100 placed on the IO stage 105 is opened by the pod opener 108. Subsequently, the second wafer conveying unit 124 of the second transfer chamber 121 picks up the wafers 200 from the substrate table 141 and conveys them to the second transfer chamber 121, and houses them in the pod 100 through the wafer carrying-in/out port 134 of the second transfer chamber 121. After all the 25 processed wafers 200 have been housed in the pod 100, the cap 100a of the pod 100 is closed by the pod opener 108. The closed pod 100 is transferred from the IO stage 105 to the following process by the rail guided vehicle.

While the foregoing operation has been described using the case in which the first furnace 202 and the first cooling unit 138 are used, the same operation applies to a case in which the second furnace 137 and the second cooling unit 139 are used. While the substrate processing unit 10 uses the spare room 122 for carrying in and the spare chamber 123 for carrying out, the spare chamber 123 may be used for carrying in and the spare room 122 may be used for carrying out.

The first furnace 202 and the second furnace 137 may be used for either the same process or different processes. In the case where the first furnace 202 and the second furnace 137 are used for different processes, for example, the first furnace 202 is used for performing a certain process on the wafers 200, for example, cleaning the insulator film formed on the substrate surface, and then the second furnace 137 may be used, for example, for forming silicon grains according to the embodiment. In the case where the first furnace 202 is used for performing a predetermined process on the wafers 200 and then the second furnace 137 is used for performing another process, it may be performed through the first cooling unit 138 or the second cooling unit 139.

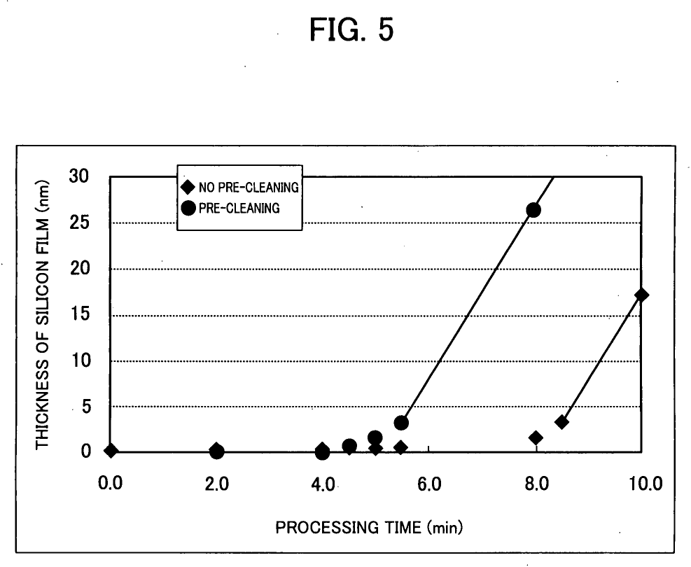

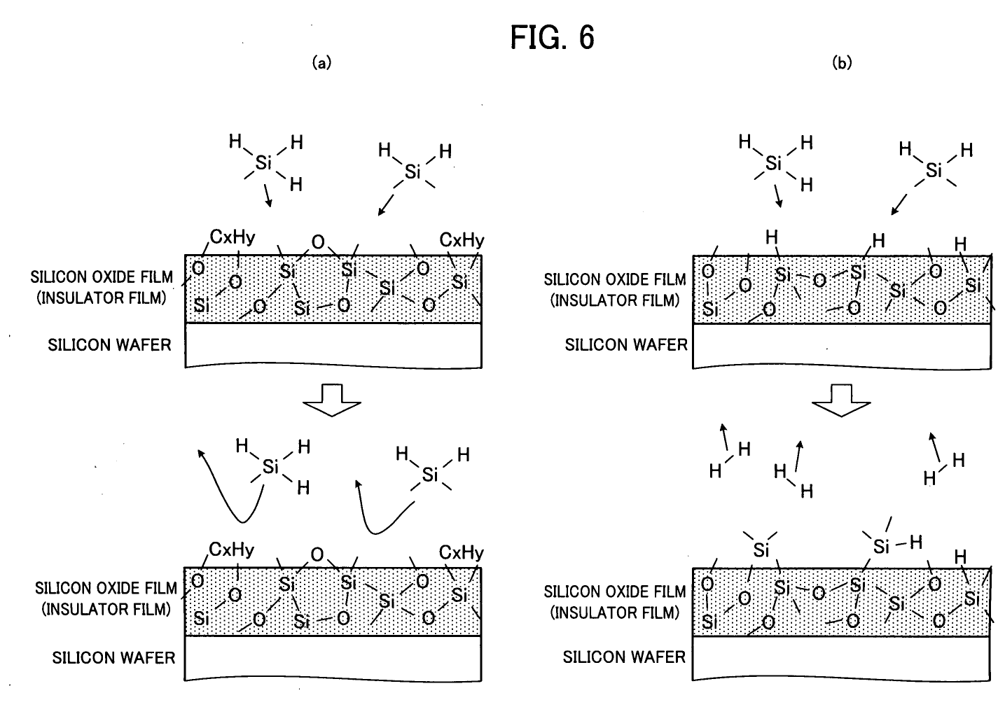

Referring to FIGS. 5 and 6, Example 1 will be described.

### EXAMPLE 1

FIG. 5 shows, in the case where a wafer is processed under the process condition in the above embodiment, how the thickness of a silicon film formed on the wafer increases with the processing time in the case where the surface (insulator film surface) of the wafer is cleaned before the wafer is processed and in the case where the wafer surface is not cleaned before the wafer is processed. The horizontal axis is scaled in terms of processing time (minute), that is, silicon-based gas feed time; the vertical axis is scaled in terms of the thickness (mm) of the silicon film formed on the insulator film on the wafer. “No pre-cleaning” means that the wafer surface is not cleaned before the wafer is processed, and “pre-cleaning” means that the wafer surface is cleaned before the wafer is processed. Both cases are under the same wafer processing conditions. In Example 1, the wafer is processed only by silicon-based gas, using no dopant gas. For silicon-based gas, monosilane (SiH₄) is used.

The normal direct processing without cleaning took more than eight minutes until the thickness of the silicon film increases, as shown in “no pre-cleaning” of FIG. 5. During the eight minutes, the wafer surface repeatedly shows such reactions as decomposition of the silicon-based gas, adsorption on the surface, migration, and dissociation. This process without pre-cleaning seems to decrease the bond density for adsorbing silicon-based gas onto the wafer surface because of contaminants to decrease the surface coverage, so that the deposition is started after eight minutes. The decrease in surface coverage means that there is the cause of the low density of silicon grains on the wafer surface. Normally, silicon grains seem to grow from low-density region in three dimensions to increase in thickness. The result shows that the formation of silicon grains cannot be controlled with such a surface state by the conditions of feeding silicon-based gas.

In contrast, in the case where cleaning is performed, it takes about five minutes until the silicon film increases in thickness, as shown in “pre-cleaning” of FIG. 5, which is shorter than that of “no pre-cleaning”. The difference of three minutes seems to depend on the number of bonds on the wafer surface. The wafer surface repeatedly shows such reactions as decomposition of the silicon-based gas, adsorption on the surface, migration, and dissociation, as described above. The pre-cleaning seems to increase the bond density for adsorbing silicon-based gas on the wafer surface, in contrast to the case of no pre-cleaning, that is, the bond density may depend on the state of the film on the wafer surface. As a result, the surface coverage is also increased.

Referring to FIG. 6, the reactions in the case of pre-cleaning and the case of no pre-cleaning will be described. FIG. 6 shows images of reactions in a case with pre-cleaning and a case without pre-cleaning. The reaction changes with the state of cleaning of the surface of the insulator film formed on the silicon substrate. That is, in the case where the pre-cleaning is not performed before the process of forming silicon grains, if the bonds of the insulator film with which silicon-based gas is to react have bonded to other molecules (CxHy, O, etc.), as shown in FIG. 6(a), little silicon grains are formed. That is, formation of silicon grains depends on the surface state and cannot be controlled by the conditions of feeding silicon-based gas. In contrast, in the case of performing pre-cleaning, the insulator film has a cleaned surface without contaminants, as shown in FIG. 6(b). If the bonds of the insulator film join to atoms, such as hydrogen (H), which are easily separated at a low temperature, silicon grains can easily be formed. That is, formation of silicon grains can be controlled by the conditions of feeding silicon-based gas.

Therefore, in the invention, formation of the nuclei of fine silicon grains is easily controlled by pre-cleaning the surface of semiconductor before it is processed in the processing chamber (reaction vessel), as described above. This ensures stable-performance semiconductor devices.

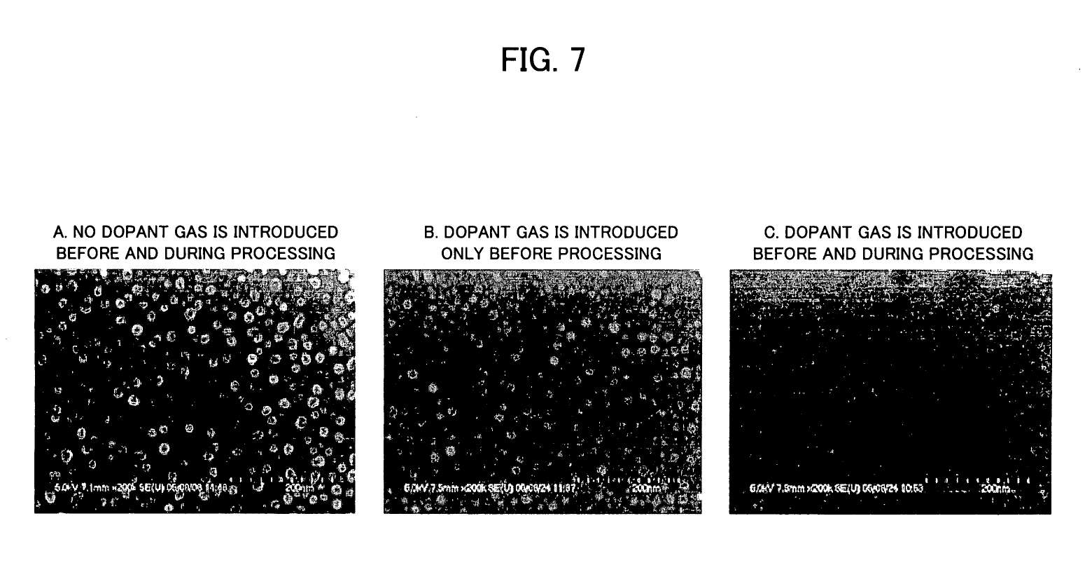

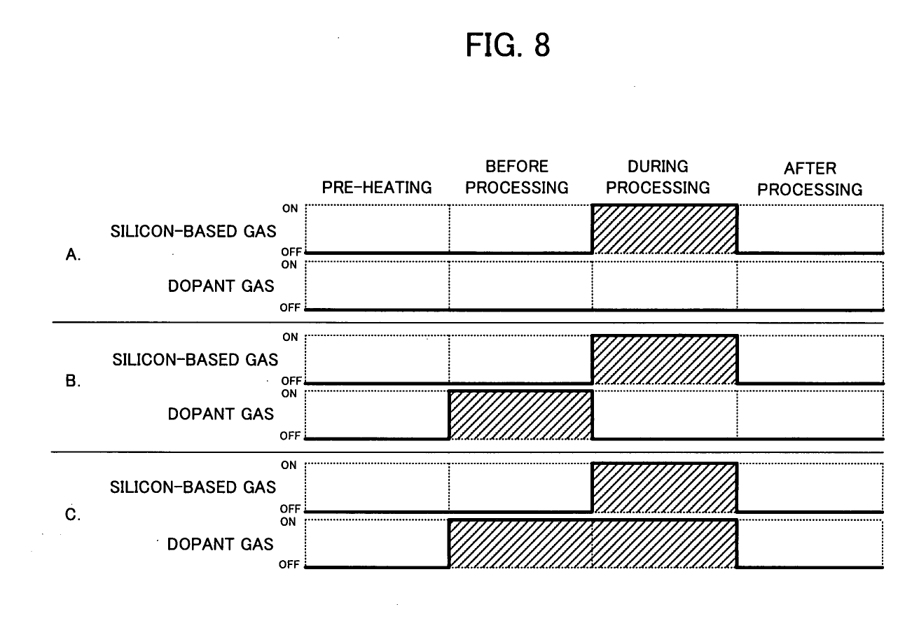

Referring to FIGS. 7 and 8, Example 2 will be described.

### EXAMPLE 2

FIG. 7 shows electron micrographs of the effects of silicon grain density control found by experiment using the furnace of the substrate processing unit 10, depending on whether dopant gas is introduced or not and difference in the timing of introduction of dopant gas. FIG. 8 shows the timing of introduction of silicon-based gas and dopant gas. In this example, monosilane (SiH₄) is used as silicon-based gas and diborane (B₂H₆) is used as dopant gas. In this example, the wafer is subjected to pre-cleaning, as in the foregoing embodiment, and then processed under specified conditions within the process conditions shown in the foregoing embodiment.

Three images A, B, and C are obtained by processing a wafer by sequences A, B, and C shown in FIG. 8, respectively. Sequence A shows a case in which only silicon-based gas is introduced and no dopant gas is introduced before and during the process of forming silicon grains (silicon grains). Sequence B shows a case in which dopant gas is introduced only before the process. Sequence C shows a case in which dopant gas is continuously introduced before and during the process. The experiment was performed with the timing of introduction of dopant gas varied.

As shown in FIG. 7, in the conventional process, like A, in which no dopant gas is introduced, silicon grains with a density of 10¹¹/cm² are formed. The density of silicon grains is increased by introduction of dopant gas, as shown in B and C.

The example shows that in the case where dopant gas is introduced before and during the process of forming silicon grains, as shown in C of FIG. 7, silicon grains with a high density of 10¹²/cm² are formed, increasing to about ten times higher than that of the case in which no dopant gas is introduced before and during the process of forming silicon grains, as shown in A of FIG. 7.

This means that, with introduction of dopant gas, the bond density for adsorbing silicon-based gas on the wafer surface and bonding state become different from that without introduction of dopant gas.

The density difference of ten times seems to depend on the state of bonds on the wafer surface. As described above, when forming silicon grains by introducing silicon-based gas, the wafer surface repeatedly shows such reactions as adsorption of silicon-based gas on the surface, migration, decomposition, and dissociation. The hydrogen dissociated from the dopant atoms or dopant gas is adsorbed to the bonds on the wafer surface, so that the density of bonds for adsorbing silicon-based gas seems to become higher than that without introduction of dopant gas, or the rate of decomposition of silicon-based gas seems to be increased with the adsorption of hydrogen for facilitating decomposition of silicon-based gas, so that the density of silicon grains has increased.

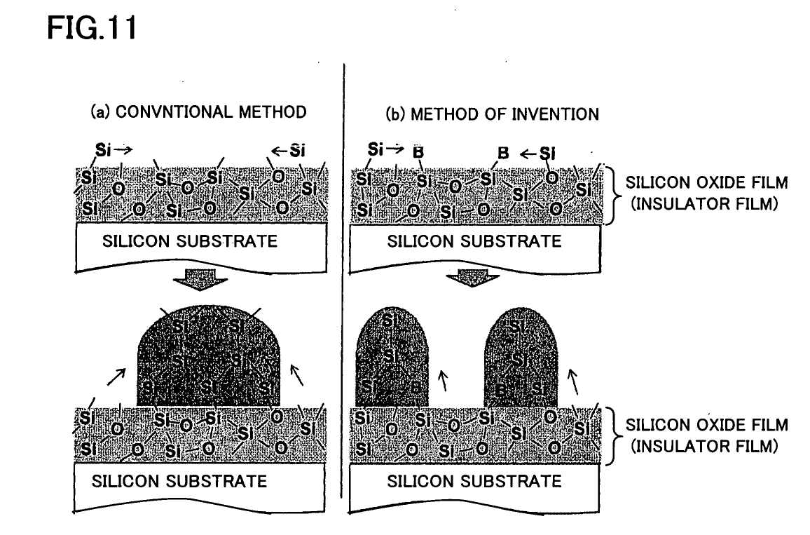

Referring to FIG. 11, the reactions in the case where dopant gas is introduced before and/or during the process of forming silicon grains and in the case where no dopant gas is introduced will be described. FIG. 11 shows images of the reactions in the case where dopant gas is introduced before and/or during the process of forming silicon grains (FIG. 11(b)) and in the case where no dopant gas is introduced (FIG. 11(a)).

In the case where dopant gas is introduced before or/and during the process of forming silicon grains on the surface of the insulator film formed on the silicon substrate, the dopant gas joins with the bonds on the surface of the insulator film. FIG. 11(b) shows a state in which dopant gas containing boron (B) is decomposed and dopant atoms, that is, boron atoms join with the bonds on the surface of the insulator film. Thus, the formation of silicon grains depends on the state of adsorption of the dopant gas or dopant atoms on the surface of the insulator film.

Silicon grains are formed such that silicon-based gas is absorbed on the surface of insulator film, and decomposed silicon atoms (Si) move on the surface of the insulator film to fix on the portion where a plurality of silicon atoms gathers. Therefore, if dopant gas is adsorbed on the surface of the insulator film, the dopant gas restricts the moving range of the silicon atoms to form fine silicon grains at high density, as shown in the lower drawing of FIG. 11(b). That is, the formation of silicon grains can be controlled according to introduction of dopant gas or conditions of introduction of dopant gas.

In contrast, in the case where no dopant gas is introduced before and/or during the process of forming silicon grains, the moving range of the silicon atoms is not restricted, as shown in FIG. 11(a). This makes it difficult to form fine silicon grains at high density as compared with the case where dopant gas is introduced.

Thus, in this invention, in order to form high-density silicon grains, dopant gas is introduced to the processing chamber before and/or during the process of forming silicon grains by introducing silicon-based gas, so that formation of nuclei for forming high-density silicon grains can be controlled, ensuring stable performance of semiconductor devices.

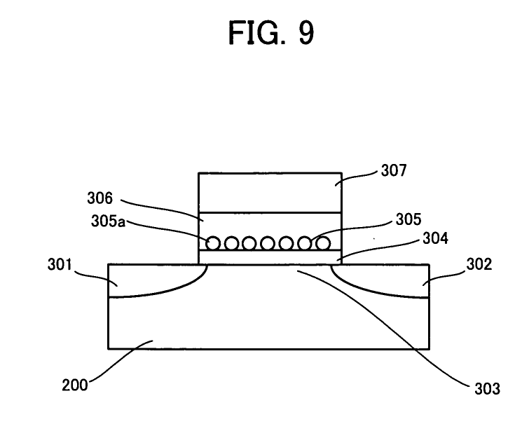

As an example of a method for manufacturing a semiconductor device, an application of the substrate processing unit and the method for processing a substrate of the invention to manufacturing a flash memory, that is, to constructing the floating gate of a flash memory by silicon quantum dots will be described. FIG. 9 is a sectional view showing part of a flash memory including a floating gate constructed of silicon quantum-dots.

First, a tunnel oxide film 304 made of an insulator such as silicon oxide film (SiO₂ film) is formed on the surface of the wafer 200. The tunnel oxide film 304 is formed by, for example, thermal oxidation such as dry oxidation or wet oxidation.

Next, a floating gate electrode 305 formed of multiple island-pattern grains, that is, silicon quantum dots 305a is formed on the tunnel oxide film 304 by application of the substrate processing unit and the method for processing a substrate according to the invention. The silicon quantum dots 305a are formed in the shape of a hemisphere or a globe.

Subsequently, an insulating layer 306 made of, for example, an insulator with a stacked structure of a silicon oxide film (SiO₂ film)/a silicon nitride film (Si₃N₄ film)/a silicon oxide film (SiO₂ film) is formed so as to cover the floating gate electrode 305. The SiO₂ film constituting the insulating layer 306 is formed by CVD using, for example, SiH₂Cl₂ gas and N₂O gas, and the Si₃N₄ film is formed by CVD using, for example, SiH₂Cl₂ gas and NH₃ gas.

Thereafter, a control gate electrode 307 formed of, for example, a polysilicon film (Poly-Si film) containing phosphorus is formed on the insulating layer 306. The control gate electrode 307 is formed by CVD using, for example, SiH₄ gas and PH₃ gas. Thus, the control gate electrode 307 is formed over the floating gate electrode 305.

Lastly, a source 301 and a drain 302 which are impurity regions doped with n-type impurities are formed on the main surface of the wafer 200 by ion implantation or the like. Between the source 301 and the drain 302 is formed a channel region 303.

Thus, the flash memory shown in FIG. 9 is manufactured.

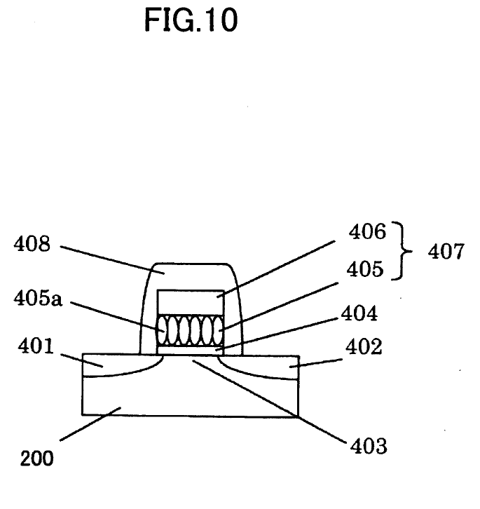

Next, as another example of a method for manufacturing a semiconductor device, an application of the substrate processing unit and the method for processing a substrate according to the invention to manufacturing a DRAM, that is, to constructing part of the gate electrodes of a DRAM by a fine-grain polysilicon film will be described. FIG. 10 is a sectional view showing part of a DRAM including a gate electrode constructed of a fine-grain polysilicon film and a metal film.

First, a gate oxide film 404 made of an insulator such as silicon oxide film (SiO₂) or a silicon oxynitride film (SiON) is formed on the surface of the wafer 200. The gate oxide film 404 is formed by, for example, thermal oxidation such as dry oxidation or wet oxidation.

Then, a polysilicon film 405 formed of fine grains 405a is formed on the gate oxide film 404 by application of the substrate processing unit and the method for processing a substrate according to the invention. Next, a metal film 406 made of tungsten (W) or the like is formed on the polysilicon film 405. The metal film 406 is formed by, for example, ALD or CVD. Thus, a gate electrode 407 constructed of the fine-grain polysilicon film 405 and the metal film 406 is formed.

Subsequently, an insulating layer 408 formed of, for example, a silicon nitride film (Si₃N₄) is formed so as to cover the gate electrode 407. The Si₃N₄ film that constitutes the insulating layer 408 is formed by CVD using, for example, SiH₂Cl₂ gas and NH₃ gas.

Lastly, a source 401 and a drain 402 which are impurity regions doped with n-type impurities are formed on the main surface of the silicon wafer 200 by ion implantation or the like. Between the source 401 and the drain 402 is formed a channel region 403.

Thus, the gate structure of the DRAM shown in FIG. 10 is manufactured.

1. A method for manufacturing a semiconductor device, comprising the steps of:
carrying a substrate having an insulator film on the surface into a processing chamber;
introducing silicon-based gas into the processing chamber to form silicon grains on the insulator film formed on the surface of the substrate; and
carrying the processed substrate out from the processing chamber; wherein
before the introduction of the silicon-based gas, dopant gas is introduced into the processing chamber.

2. The method for manufacturing a semiconductor device according to claim 1, wherein the dopant gas is introduced into the processing chamber also during the introduction of the silicon-based gas.

3. The method for manufacturing a semiconductor device according to claim 1, further comprising the step of cleaning the surface of the insulator film formed on the surface of the substrate before the step of carrying the substrate into the processing chamber.

4. The method for manufacturing a semiconductor device according to claim 1, further comprising the step of cleaning the surface of the insulator film formed on the surface of the substrate with a dilute hydrofluoric solution before the step of carrying the substrate into the processing chamber.

5. The method for manufacturing a semiconductor device according to claim 1, wherein in the process of forming silicon grains, island-pattern silicon grains are formed by stopping the growth of silicon grains before the silicon grains come into contact with one another.

6. The method for manufacturing a semiconductor device according to claim 1, wherein in the process of forming silicon grains, continuous silicon grains are formed by continuing the growth of silicon grains until the silicon grains come into contact with one another.

7. The method for manufacturing a semiconductor device according to claim 1, wherein the silicon-based gas is SiH₄ or Si₂H₆ and the dopant gas is PH₃, B₂H₆, BCl₃, or AsH₃.

8. A method for manufacturing a semiconductor device, comprising the steps of:
carrying a substrate having an insulator film on the surface into a processing chamber;
introducing silicon-based gas into the processing chamber to form island-pattern silicon grains on the insulator film formed on the surface of the substrate; and
carrying the processed substrate out from the processing chamber; wherein
before and/or during the introduction of the silicon-based gas, dopant gas is introduced into the processing chamber.

9. The method for manufacturing a semiconductor device according to claim 8, further comprising the step of cleaning the surface of the insulator film formed on the surface of the substrate before the step of carrying the substrate into the processing chamber.

10. A substrate processing apparatus comprising:
a processing chamber for processing a substrate having an insulator film on the surface;
a silicon gas feed system for feeding silicon-based gas into the processing chamber;
a dopant gas feed system for feeding dopant gas into the processing chamber;
an exhaust system for exhausting an interior of the processing chamber;
a heater for heating the substrate in the processing chamber; and
a controller that controls the silicon gas feed system, the dopant gas feed system and the heater so as to feed silicon-based gas into the processing chamber to form silicon grains on the insulator film formed on the surface of the substrate, and to feed dopant gas into the processing chamber before the introduction of the silicon-based gas.

11. The substrate processing apparatus according to claim 10, wherein the controller controls the silicon gas feed system, the dopant gas feed system and the heater so as to feed dopant gas into the processing chamber also during the introduction of the silicon-based gas.

12. A substrate processing apparatus comprising:
a processing chamber for processing a substrate having an insulator film on the surface;
a silicon gas feed system for feeding silicon-based gas into the processing chamber;
a dopant gas feed system for feeding dopant gas into the processing chamber;
an exhaust system for exhausting an interior of the processing chamber;
a heater for heating the substrate in the processing chamber; and
a controller that controls the silicon gas feed system, the dopant gas feed system and the heater so as to feed silicon-based gas into the processing chamber to form island-pattern silicon grains on the insulator film formed on the surface of the substrate, and to feed dopant gas into the processing chamber before and/or during the introduction of the silicon-based gas.
